(19) United States
(12) Patent Application Publication
(10) Pub. No.: US 2010/0051323 A1
(43) Pub. Date: Mar. 4, 2010

(54) PRINTED WIRING BOARD AND CONDUCTIVE WIRING LAYER

(75) Inventor: Kishio Yokouchi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/487,920

(22) Filed: Jun. 19, 2009

(30) Foreign Application Priority Data
Aug. 29, 2008 (JP) 2008-222766

(51) Int. Cl. H05K 1/09; H05K 1/00

(52) U.S. Cl. 174/250; 174/126.1

(57) ABSTRACT

A printed wiring board with an insulating layer formed of an insulating material and a conductive wiring layer formed on a front surface of the insulating layer. The conductive wiring layer has a conductor and a filler. The filler is embedded in the conductor. The filler has a coefficient of thermal expansion smaller than the conductor.

### CROSS-REFERENCE TO RELATED APPLICATION

This application is based upon and claims the benefit of priority of the prior Japanese Patent Application No. 2008-222766, filed on Aug. 29, 2008, the entire contents of which are incorporated herein by reference.

### FIELD

The present invention relates to a printed wiring board and a conductive wiring layer.

### BACKGROUND

A printed wiring board includes a core substrate containing, for example, carbon fiber. The core substrate alone is securely stiff to retain its shape. A buildup layer is formed in a laminated structure on the front surface or back surface of the core substrate. The buildup layer includes an insulating layer and a conductive wiring layer superimposed in turn. The insulating layer is made of resin material (see, for example, Japanese Laid-Open Patent Applications 9-153666, 2005-174828, 2001-167633 and 2002-299833).

The coefficient of thermal expansion of the conductive wiring layer in a buildup layer is significantly different from that of the core substrate. As a result, for example, an extremely large stress is generated in an interface between the conductive wiring layer and the insulating layer. Cracks appear in the conductive wiring layer or insulating layer based on such a stress. The conductive wiring layer may be broken due to an appearance of cracks.

### SUMMARY

According to an aspect of the invention, a printed wiring board includes: an insulating layer formed of an insulating material; and a conductive wiring layer formed on a front surface of the insulating layer. The conductive wiring layer has a conductor and a filler. The filler is embedded in the conductor. The filler has a coefficient of thermal expansion smaller than the conductor.

It is to be understood that both the foregoing general description and the following detailed description are exemplary, and do not restrict the invention as claimed.

### BRIEF DESCRIPTION OF DRAWINGS

The above and other objects, features and advantages of the present invention will become apparent from the following description of the embodiments in conjunction with the accompanying drawings, wherein:

FIG. 1 schematically illustrates a cross-sectional structure of a printed wiring board according to an embodiment of the present invention;

FIG. 2 is a sectional view obtained by enlarging a conductive wiring layer according to an embodiment;

FIG. 3 schematically illustrates a process to stick a prepreg and copper foil on a front surface of a core substrate;

FIG. 4 schematically illustrates a process to form a photo resist on the front surface of the copper foil;

FIG. 5 schematically illustrates a process to perform an etching process on the copper foil based on the photo resist;

FIG. 6 schematically illustrates a process to form a through-hole in the prepreg;

FIG. 7 schematically illustrates a process to form a via based on plating treatment; and

FIG. 8 is a sectional view obtained by enlarging the conductive wiring layer according to an embodiment of the present embodiment.

### DESCRIPTION OF EMBODIMENTS

An embodiment of the present invention will be described below with reference to the attached drawings.

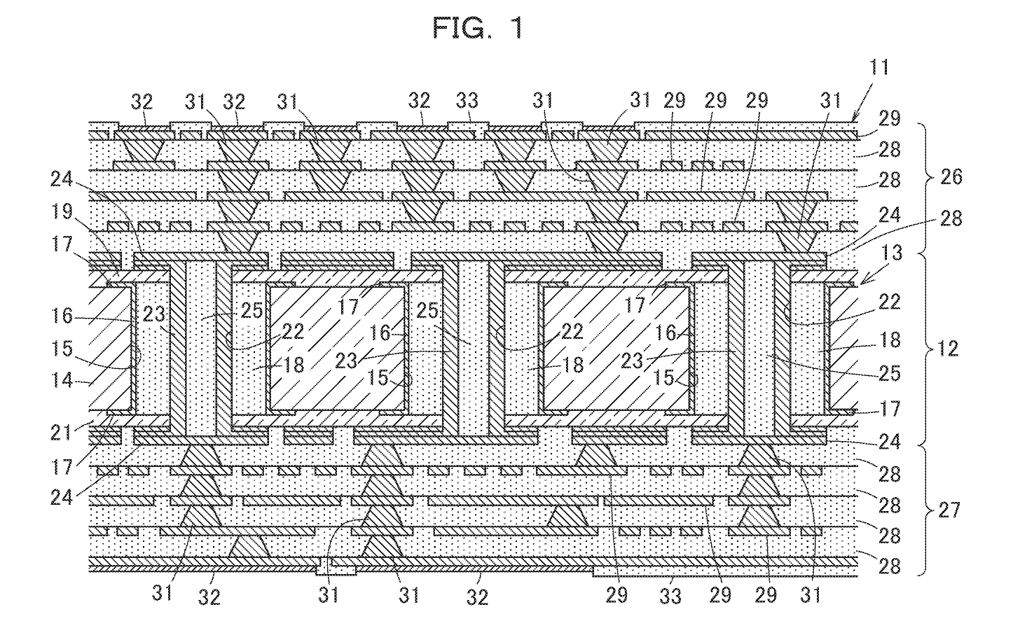

FIG. 1 schematically illustrates the cross-sectional structure of a printed wiring board 11 according to an embodiment of the present invention. The printed wiring board 11 is employed, for example, in a probe card. A probe card is mounted in an electronic device such as a probe device. However, the printed wiring board 11 may also be employed in other electronic devices.

The printed wiring board 11 includes a core substrate 12. The core substrate 12 alone has sufficient rigidity to be able to retain its shape. The core substrate 12 includes a flat core layer 13. The core layer 13 includes a conductive layer 14. A carbon fiber cloth is embedded in the conductive layer 14. The fiber of the carbon fiber cloth extends in an in-plane direction of the core layer 13. Therefore, thermal expansion in the in-plane direction is suppressed in the conductive layer 14. The carbon fiber cloth has conductivity. When the conductive layer 14 is formed, the carbon fiber cloth is impregnated with resin material. Thermosetting resin such as epoxy resin is employed as the resin material. The carbon fiber cloth is formed of one of woven fabric and nonwoven fabric of carbon fiber threads.

A plurality of prepared through-holes 15 is formed in the core layer 13. The prepared through-holes 15 penetrate the core layer 13. The prepared through-hole 15 provides, for example, a cylindrical space. The axial center of the cylindrical space is orthogonal to the front surface and the back surface of the core layer 13. By action of the prepared through-hole 15, circular openings are partitioned on the front surface and the back surface of the core layer 13.

A large-diameter conductive via 16 is formed in the prepared through-hole 15. The large-diameter via 16 is formed in a cylindrical shape along an inner wall surface of the prepared through-hole 15. The large-diameter via 16 is connected to annular conductive lands 17 on the front surface and the back surface of the core layer 13. The conductive lands 17 expand on the front surface and the back surface of the core layer 13. The large-diameter via 16 and the conductive lands 17 are formed of a conductive material such as copper (Cu).

An inner space of the large-diameter via 16 inside the prepared through-hole 15 is filled with a prepared filler 18 made of insulating resin. The prepared filler 18 expands in the cylindrical shape along the inner wall surface of the large-diameter via 16. Thermosetting resin material such as epoxy resin is employed as the prepared filler 18. For example, a ceramic filler is embedded in epoxy resin.

The core substrate 12 includes insulating layers 19 and 21 laminated on the front surface and the back surface of the core layer 13 respectively. The insulating layers 19 and 21 are each caught through the back surface thereof by the front surface and the back surface of the core layer 13 respectively. The insulating layers 19 and 21 sandwich the core layer 13. The insulating layers 19 and 21 cover and hang over the prepared filler 18. The insulating layers 19 and 21 have insulation properties.

A glass fiber cloth is embedded in the insulating layers 19 and 21. The fiber of the glass fiber cloth extends along the front surface and the back surface of the core layer 13. When the insulating layers 19 and 21 are formed, the glass fiber cloth is impregnated with resin material. Thermosetting resin such as epoxy resin is employed as the resin material. The glass fiber cloth is formed of one of woven fabric and nonwoven fabric of glass fiber threads.

The core substrate 12 has a plurality of through-holes 22 formed therein. The through-holes 22 penetrate the core substrate 12. The through-holes 22 are arranged inside the prepared through-holes 15. The prepared filler 18 is penetrated by the through-hole 22. Here, the through-hole 22 provides a cylindrical space. The through-hole 22 and the prepared through-hole 15 are coaxially formed. With an action of the through-hole 22, circular openings are partitioned on the front surface and the back surface of the core substrate 12.

A conductive small-diameter via 23 is formed in the through-hole 22. The small-diameter via 23 is formed in the cylindrical shape along the inner wall surface of the through-hole 22. By action of the prepared filler 18, the large-diameter via 16 and the small-diameter via 23 are insulated from each other. The small-diameter via 23 is formed of a conductive material such as copper.

Conductive lands 24 are formed on the front surface of the insulating layers 19 and 21. The small-diameter via 23 is connected to the conductive land 24 on the front surface of the insulating layer 19 or 21. The conductive land 24 is formed of a conductive material such as copper. An inner space of the small-diameter via 23 between the conductive lands 24 is filled with a filler 25 made of insulating resin. The filler 25 is formed, for example, in the cylindrical shape. Thermosetting resin material such as epoxy resin is employed as the filler 25. For example, a ceramic filler is embedded in the epoxy resin.

Buildup layers 26 and 27 are formed on the front surface and the back surface of the core substrate 12, respectively. The buildup layers 26 and 27 depend on the core substrate 12 for stiffness to retain their shape. The buildup layers 26 and 27 are each caught through the back surface thereof by the front surface and the back surface of the core substrate 12, respectively. The buildup layers 26 and 27 sandwich the core substrate 12. The buildup layers 26 and 27 are each formed of a laminated body of a plurality of insulating layers 28 and conductive wiring layers 29. The insulating layer 28 and conductive wiring layer 29 are alternately laminated. The thickness of the conductive wiring layer 29 is set, for example, to the range of 30 μm to 60 μm.

The conductive wiring layers 29 in different layers are electrically connected by a via 31. When the via 31 is formed, a through-hole is formed in the insulating layer 28 between the conductive wiring layers 29. The through-hole is filled with a conductive material. The insulating layer 28 is formed of, for example, thermosetting resin such as epoxy resin. The conductive wiring layer 29 is formed of a conductive material described later. Details of the conductive material will be described later. The via 31 is formed of a conductive material such as copper.

A conductive pad 32 is exposed on the front surface of the buildup layers 26 and 27. The conductive pad 32 is formed of a conductive material such as copper. An overcoat layer 33 is laminated in portions of the front surface excluding the conductive pad 32 of the buildup layers 26 and 27. A resin material, for example, is employed as the overcoat layer 33.

The conductive pad 32 exposed on the front surface of the printed wiring board 11 is electrically connected to any of the conductive pads 32 exposed on the back surface of the printed wiring board 11. If the printed wiring board 11 is mounted in a probe device, the conductive pad 32 is connected, for example, to an electrode terminal of the probe device on the back surface of the printed wiring board 11. If, for example, a semiconductor wafer is mounted on the front surface of the printed wiring board 11, the conductive pad 32 receives, for example, a bump electrode of the semiconductor wafer on the front surface of the printed wiring board 11. The conductive pad 32 is connected to the bump electrode. In this way, an inspection of the semiconductor wafer is performed based on, for example, a temperature cycling test.

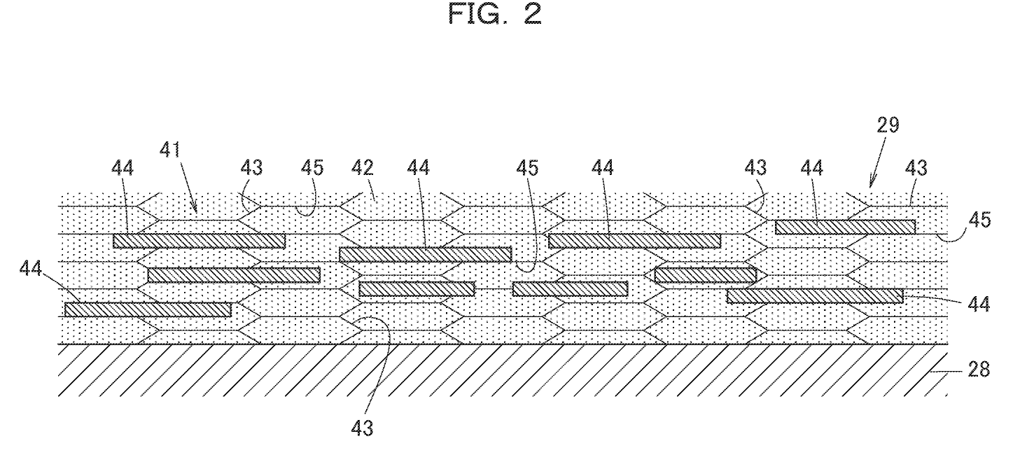

FIG. 2 illustrates a cross-sectional structure of the conductive wiring layer 29. The conductive wiring layer 29 is formed of a conductive material 41. The conductive material 41 includes a conductor 42. The conductor 42 may be formed of a material having high electro-conductivity such as copper (Cu), copper alloys, silver (Ag), silver alloys, gold (Au), gold alloys, aluminum (Al), and aluminum alloys. Also, the conductor 42 may be formed of a material having low resistivity such as nickel (Ni) and nichrome (Nr). In the embodiment, copper is employed as the conductor 42. Specifically, the conductor 42 is formed of an aggregate of innumerable copper crystals 43.

A filler 44 of conductive body is embedded in the conductor 42. The filler 44 is arranged by being dispersed in the conductor 42. The filler 44 is arranged along an interface 45 of the copper crystals 43. The filler 44 has a coefficient of thermal expansion smaller than the conductor 42. A carbon material such as carbon fiber and/or carbon nanotubes maybe employed as the filler 44. Here, for example, carbon fiber in the cylindrical shape is employed as the filler 44. Elements constituting the filler 44 are chemically bonded to those constituting the conductor 42. The filler 44 is oriented in parallel with the front surface of the insulating layer 28 and in the in-plane direction of the printed wiring board 11. As a result, thermal expansion in the in-plane direction is severely restricted in the conductive wiring layer 29.

Here, the average diameter of the filler 44 is preferably set, for example, in the range of 0.3 μm to 3.0 μm. If the average diameter is set to less than 0.3 μm, homogeneity of dispersion of the filler 44 in the melted conductor 42 is considered to deteriorate during formation of the conductive wiring layer 29 described later. If the average diameter is set to more than 3.0 μm, flatness of the front surface of the conductive wiring layer 29 is considered to deteriorate. At the same time, as described above, homogeneity of dispersion of the filler 44 in the melted conductor 42 is considered to deteriorate.

The filler 44 preferably has a length at least ten times the average diameter in the in-plane direction of the printed wiring board 11. Here, the average length is set, for example, in the range of 3 μm to 50 μm. If the average length is set less than ten times the average diameter, sufficient stiffness of the filler 44 is considered not to be securable. If the average length is too long, homogeneity of dispersion of the filler 44 in the conductor 42 is considered to deteriorate. At the same time, protrusion of the filler 44 from the contour of the conductive wiring layer 29 to the outside is assumed. Based on such protrusion, the filler 44 may come into contact with the adjacent conductive wiring layer 29. In such a case, a short circuit may be caused based on migration of copper ions having a tendency of moving along the filler 44. Therefore, the average length of the filler 44 is preferably set to about 50 μm or less.

In the printed wiring board 11 described above, the conductive wiring layer 29 is formed of the conductive material 41. The filler 44 is embedded in the conductor 42 of the conductive material 41. The filler 44 has a coefficient of thermal expansion smaller than the conductor 42. As a result, for example, the coefficient of thermal expansion of the conductive wiring layer 29 is kept lower compared with a conventional conductive wiring layer formed, for example, from copper alone. In this manner, for example, the coefficient of thermal expansion of the buildup layers 26 and 27 is adjusted to that of the core substrate 12. Stress generation in the printed wiring board 11 is suppressed. An appearance of cracks in the buildup layers 26 and 27 is avoided. The breaking of the conductive wiring layer 29 is avoided.

Moreover, as described above, in the conductive layer 14, the fiber of a carbon fiber cloth extends in the in-plane direction of the core layer 13. Therefore, thermal expansion in the in-plane direction is severely restricted in the conductive layer 14. Similarly, the filler 44, that is, the carbon fiber in the conductive wiring layer 29 extends in parallel with the front surface of the insulating layer 28 and in the in-plane direction of the printed wiring board 11. As a result, thermal expansion in the in-plane direction is suppressed in the conductive wiring layer 29. Therefore, thermal expansion in the in-plane direction of the printed wiring board 11 is reliably restricted. Stress generation in the printed wiring board 11 is strictly avoided. The breaking of the conductive wiring layer 29 is reliably avoided.

In addition, the filler 44 has conductivity and thus, a rise in DC resistance of the conductive wiring layer 29 is avoided even if the filler 44 is embedded in the conductor 42. Further, the filler 44 is formed of carbon fiber. Carbon fiber is lighter than the conductor 42, that is, copper. As a result, the conductive wiring layer 29 is made lighter based on embedding of the filler 44. At the same time, the amount of copper employed at a high cost in the conductive wiring layer 29 can be reduced based on the filler 44. As a result, the present invention can contribute to lower costs of the conductive wiring layer 29, that is, printed wiring board 11.

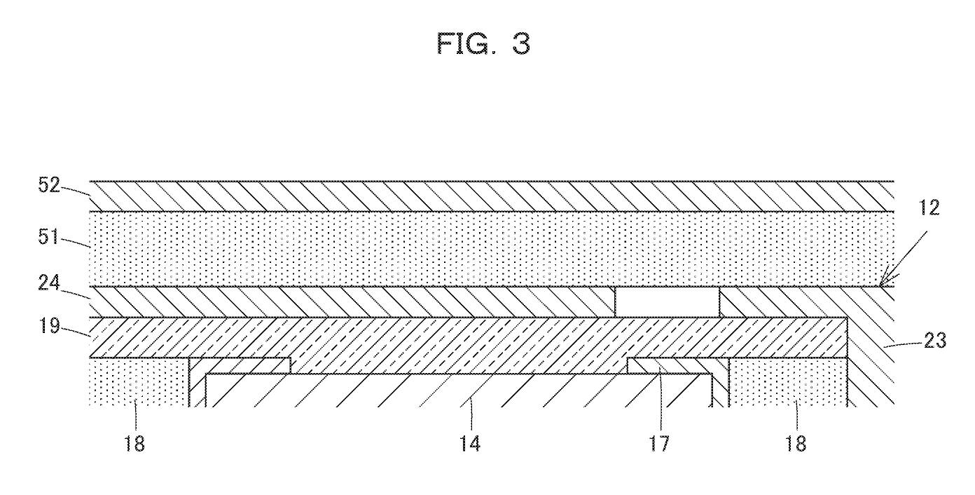

Next, the manufacturing method of the printed wiring board 11 will be described. First, the core substrate 12 is prepared. As depicted in FIG. 3, a prepreg 51 and copper foil 52 are superimposed on the front surface of the core substrate 12. The prepreg 51 is formed of a resin material such as epoxy resin. The copper foil 52 is stuck on the front surface of the prepreg 51. Heating treatment is performed on the prepreg 51. The prepreg 51 patterns the shape of the core substrate 12 based on the heating treatment. As a result, the shape of the prepreg 51 absorbs irregularities on the front surface of the core substrate 12. Epoxy resin is completely cured in the prepreg 51. In this manner, the back surface of the prepreg 51 is stuck to the front surface of the core substrate 12.

The copper foil 52 is formed before the prepreg 51 is stuck. For the formation of the copper foil 52, a predetermined amount of filler 44 is injected into the melted conductor 42, that is, copper. For example, the filler 44 in the amount of 5% by volume is injected into the conductor 42. Carbon fiber is employed as the filler 44. The filler 44 is stirred in the conductor 42. The filler 44 is dispersed in the conductor 42. A resin coat is formed on the surface of each filler 44 for dispersion. For example, an acrylic resin material having high thermal decomposition properties is employed as the resin coat. Copper is rolled at a temperature below the melting point of copper. In this manner, a copper plate piece is formed. Subsequently, the plate piece is further rolled in an environment at about room temperature. In this manner, the copper foil 52 is formed. In the copper foil 52, the filler 44 is oriented in parallel with the front surface of the copper foil 52 based on the rolling. Incidentally, the filler 44 may be dispersed in the conductor 42 based on, for example, the gas atomization process.

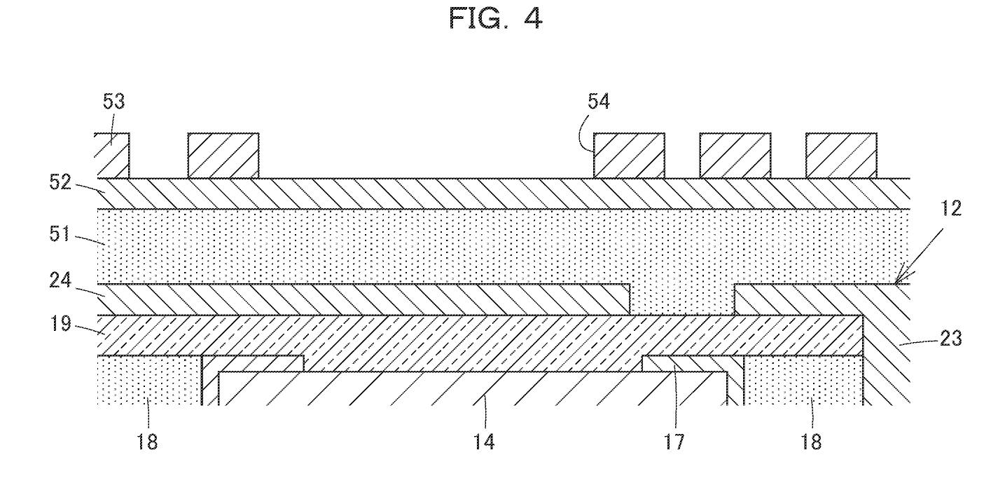

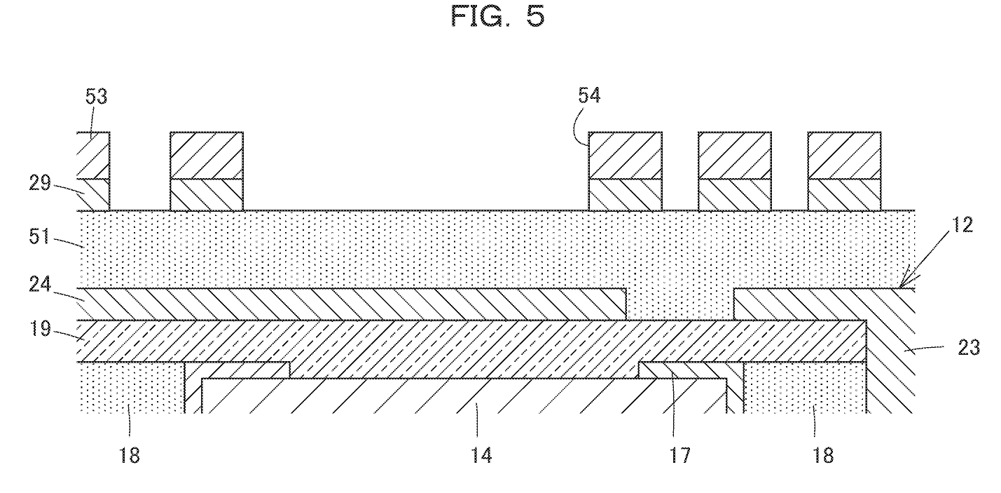

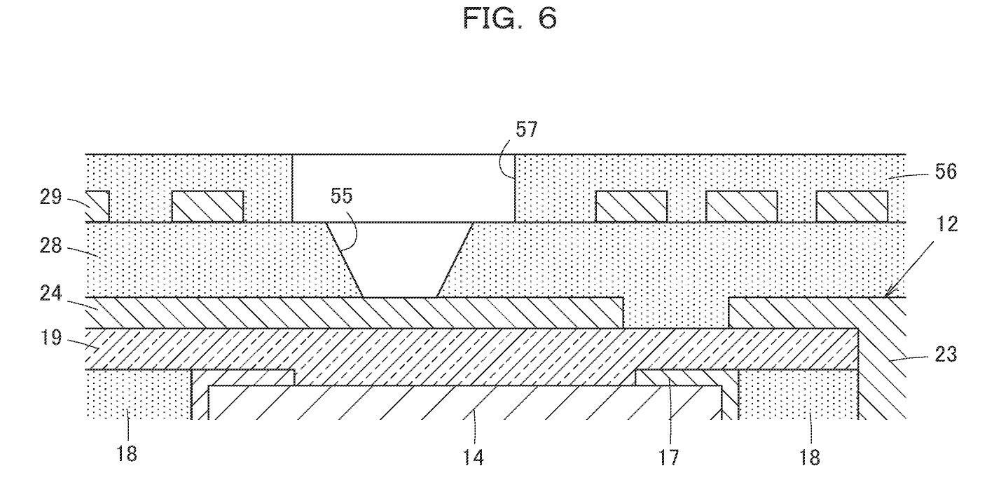

As depicted in FIG. 4, a photo resist 53 is formed on the front surface of the copper foil 52 in a predetermined pattern. The photo resist 53 patterns a void 54 on the front surface of the copper foil 52. An etching process is performed on the copper foil 52 based on the photo resist 53. As a result, as depicted in FIG. 5, the copper foil 52 in the void 54 is removed. In this manner, the conductive wiring layer 29 is formed on the front surface of the prepreg 51. The photo resist 53 is removed from the front surface of the prepreg 51. After the photo resist 53 is removed, as depicted in FIG. 6, a through-hole 55 is formed at a predetermined position in the prepreg 51. For the formation, for example, a laser is employed. The conductive land 24 of the core substrate 12 is exposed in the through-hole 55.

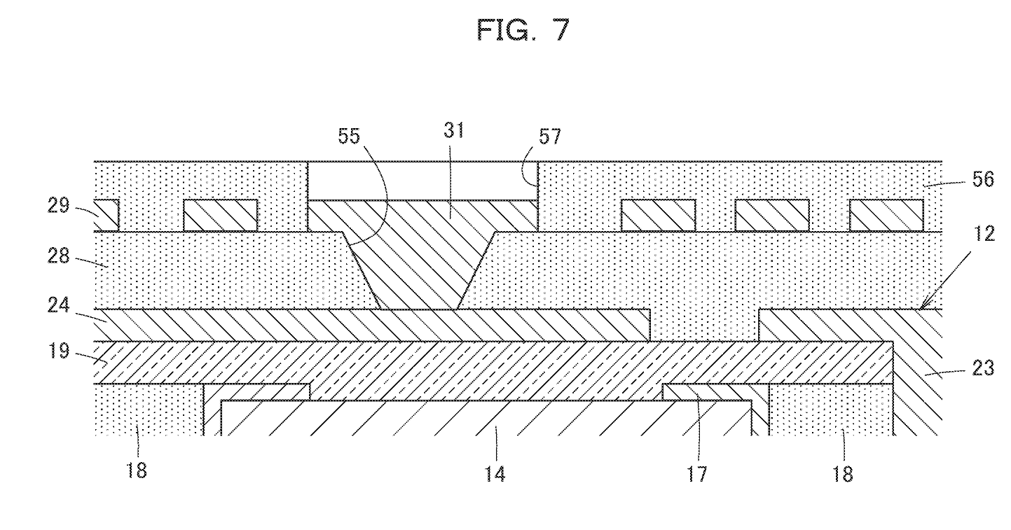

A photo resist 56 is formed on the front surface of the prepreg 51 according to a predetermined pattern. The photo resist 56 patterns a void 57 on the front surface of the prepreg 51. The through-hole 55 is arranged in the void 57. Plating treatment is performed on the front side of the prepreg 51. Subsequently, the photo resist 56 is removed from the front surface of the prepreg 51. As a result, as depicted in FIG. 7, a via 31 is formed in the through-hole 55. The prepreg 51 constitutes the insulating layer 28. Subsequently, the formation of the insulating layer 28 and the conductive wiring layer 29 is repeated. In this manner, as many as the prescribed number of laminations of the insulating layer 28 and the conductive wiring layer 29 are formed. The conductive pad 32 and the overcoat layer 33 are formed in the insulating layer 28 of the top layer. In this manner, the printed wiring board 11 is formed.

The inventors have verified effects of the present invention. In an example, a copper foil 52 of the present embodiment was fabricated. The filler 44, that is, carbon fiber was embedded in the conductor 42. The carbon fiber extended in parallel with the front surface of the copper foil 52. The filler 44 was contained in the ratio of 5% by volume to the total volume of the conductor 42 and the filler 44. In a comparative example, on the other hand, the copper foil was formed of the conductor 42, that is, copper alone. In this case, coefficients of thermal expansion in the in-plane direction in the present embodiment and the comparative example were measured. As a result, the coefficient of thermal expansion of 5 to 7 ppm/° C. in the in-plane direction was measured for the example. The coefficient of thermal expansion of 17 ppm/° C. in the in-plane direction was measured for the comparative example. This shows that the coefficient of thermal expansion is significantly reduced compared with the comparative example.

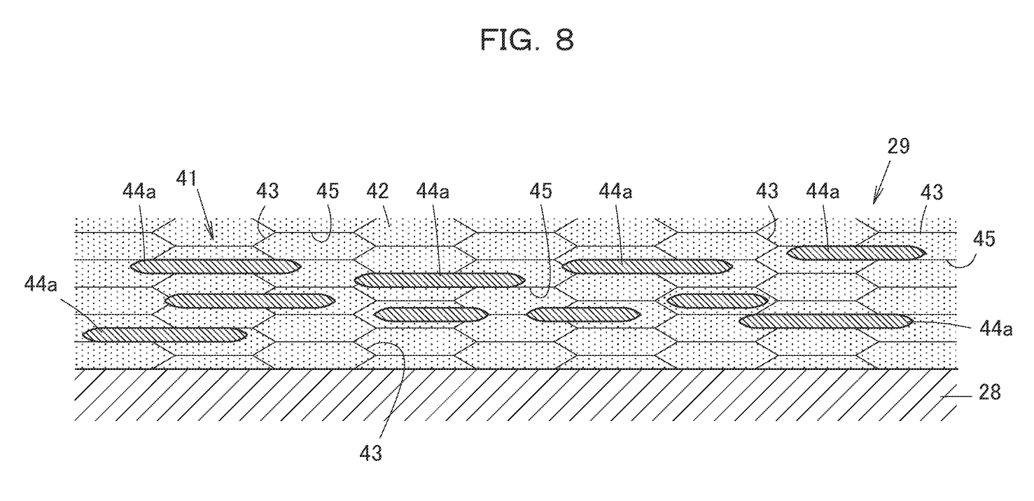

As depicted in FIG. 8, a filler 44a may be embedded in the conductive material 41 of the conductive wiring layer 29. An inorganic dielectric material such as alumina (Al₂O₃), silicon nitride (Si₃N₄), mullite (Al₆O₁₃Si₂), and boron nitride (BN) is employed as the filler 44a. The filler 44a is arranged along the interface 45 of the copper crystals 43. The filler 44a has a coefficient of thermal expansion smaller than the conductor 42. The filler 44a is formed, for example, from fiber in the cylindrical shape, that is, whisker. The filler 44a is oriented in parallel with the front surface of the insulating layer 28 and in the in-plane direction of the printed wiring board 11. As a result, thermal expansion in the in-plane direction is severely restricted in the conductive wiring layer 29. The conductive wiring layer 29 is formed in the same way as described above. In addition, the same reference numerals refer to equivalent components or structures as before.

In the printed wiring board 11 as described above, the filler 44a is embedded in the conductive material 41. The filler 44a has a coefficient of thermal expansion smaller than the conductor 42. As a result, the conductive wiring layer 29 with lower coefficient of thermal expansion may be provided as compared with a conductive wiring layer which is formed, for example, of only copper. Moreover, the filler 44a extends in parallel with the front surface of the insulating layer 28 and in the in-plane direction of the printed wiring board 11. As a result, thermal expansion in the in-plane direction is severely restricted in the conductive wiring layer 29. Thermal expansion in the in-plane direction of the printed wiring board 11 is reliably restricted. Stress generation in the printed wiring board 11 is strictly avoided. The breaking of the conductive wiring layer 29 is reliably avoided.

In addition, the filler 44a is formed of a dielectric material and thus, a rise in high-frequency electric resistance of the conductive wiring layer 29 is avoided even if the filler 44a is embedded in the conductor 42. The surface area increases in the conductor 42 based on the filler 44a. Despite the so-called skin effect, channels of current are adequately secured in the conductive wiring layer 29. Further, an inorganic dielectric material is lighter than the conductor 42, that is, copper. The conductive wiring layer 29 is made lighter based on the filler 44a. At the same time, the amount of copper employed in the conductive wiring layer 29 is reduced. Thus, lower costs of the conductive wiring layer 29 (i.e., the printed wiring board 11) are realized.

The inventors have verified effects of the present invention. In an example, copper foil 52 according to the present embodiment was fabricated. The filler 44a, that is, alumina whisker was embedded in the conductor 42. The filler 44a extended in parallel with the front surface of the copper foil 52. The filler 44a contained the ratio of 5% by volume to the total volume of the conductor 42 and the filler 44a. In a comparative example, the copper foil was formed of the conductor 42, that is, copper alone. In this case, coefficients of thermal expansion in the in-plane direction in the present embodiment and the comparative example were measured. As a result, the coefficient of thermal expansion of 14 ppm/° C. in the in-plane direction was measured for the example. The coefficient of thermal expansion of 17 ppm/° C. in the in-plane direction was measured for the comparative example. This shows that the coefficient of thermal expansion is reduced compared with the comparative example.

In addition, the present invention can be applied to other printed wiring boards such as a back board, system board, and package substrate incorporated in a server computer. The fillers 44 and 44a may be formed of woven fabric or nonwoven fabric. In addition, the fillers 44 and 44a may be contained in other conductive materials than the conductive wiring layer 29 in the printed wiring board 11.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

1. A printed wiring board comprising:
an insulating layer formed of an insulating material; and
a conductive wiring layer formed on a planar surface of the insulating layer, the conductive wiring layer having a conductor and a filler, wherein the filler is embedded in the conductor, and the filler has a coefficient of thermal expansion smaller than the conductor.

2. The printed wiring board according to claim 1, wherein the filler is formed of a carbon-based material.

3. The printed wiring board according to claim 2, wherein the filler is formed of fiber oriented along the planar surface of the insulating layer.

4. The printed wiring board according to claim 1, wherein the filler is formed of an inorganic dielectric material.

5. The printed wiring board according to claim 4, wherein the filler is formed of fiber oriented along the planar surface of the insulating layer.

6. A conductive wiring layer comprising:
a conductor; and
a filler embedded in the conductor and having a coefficient of thermal expansion smaller than the conductor.

7. The conductive wiring layer according to claim 6, wherein the filler is formed of a carbon-based material.

8. The conductive wiring layer according to claim 7, wherein the filler is formed of fiber.

9. The conductive wiring layer according to claim 8, wherein the filler is oriented in a direction of rolling based on rolling of the conductor.

10. The conductive wiring layer according to claim 9, wherein the filler is dispersed within the conductor based on a gas atomization.

11. The conductive wiring layer according to claim 6, wherein the filler is formed of an inorganic dielectric material.

12. The conductive wiring layer according to claim 11, wherein the filler is formed of fiber.

13. The conductive wiring layer according to claim 12, wherein the filler is oriented in a direction of rolling based on rolling of the conductor.

14. The conductive wiring layer according to claim 13, wherein the filler is dispersed within the conductor based on a gas atomization.
